(19) United States
(12) Patent Application Publication
(10) Pub. No.: US 2025/0306144 A1
(43) Pub. Date: Oct. 2, 2025

(54) MAGNETIC RESONANCE SYSTEM AND RADIO FREQUENCY LOCAL COIL FOR MAGNETIC RESONANCE SYSTEM

(71) Applicant: GE Precision Healthcare LLC, Waukesha, WI (US)

(72) Inventors: Xuelian Lu, Beijing (CN); Kun Wang, Beijing (CN); Jiabin Yao, Beijing (CN); Cunli Zhang, Beijing (CN); Yulong Duan, Beijing (CN); Yanchun Zheng, Beijing (CN)

(21) Appl. No.: 19/088,278

(22) Filed: Mar. 24, 2025

(30) Foreign Application Priority Data
Mar. 27, 2024 (CN) 202410357522.0

(51) Int. Cl. G01R 33/34; G01R 33/341

(52) U.S. Cl. CPC G01R 33/34084; G01R 33/341

(57) ABSTRACT

A magnetic resonance system and a radio frequency local coil for the magnetic resonance system are provided. The radio frequency local coil includes a flexible main body portion and an extension portion. The flexible main body portion is deformable in a first direction to at least partially surround a region to be scanned of a subject, the flexible main body portion including a main body coil circuit. The extension portion is connected to the flexible main body portion, and the extension portion includes a compensation circuit for connecting to the main body coil circuit to form a first transmit coil, wherein the compensation circuit has a resonant frequency that is the same as a radio frequency transmit frequency of the magnetic resonance system.

### CROSS REFERENCE TO RELATED APPLICATIONS

The present application claims priority and benefit of Chinese Patent Application No. 202410357522.0 filed on Mar. 27, 2024, which is incorporated herein by reference in its entirety.

### TECHNICAL FIELD

Embodiments of the present application relate to the technical field of medical imaging, and relate in particular to a magnetic resonance system and a radio frequency local coil for the magnetic resonance system.

### BACKGROUND

Magnetic resonance systems have been widely used in the field of medical diagnosis. Existing magnetic resonance systems generally have a main magnet, a radio frequency coil, a gradient coil, and the like. The radio frequency coil transmits a radio frequency excitation signal for exciting a scanned subject to generate a magnetic resonance signal, based on which a medical image of the scanned subject can be reconstructed.

Currently, the radio frequency coil includes a transmit/receive coil or a receive coil. The transmit coil includes, for example, a body coil, which is disposed along a scanning chamber to surround the scanned subject. The body coil is capable of receiving a radio frequency excitation pulse to generate a radio frequency excitation signal for exciting the whole body of the scanned subject, and is therefore suitable for whole body imaging.

The transmit coil may further include a local coil. When a medical image of a local body part needs to be obtained, a corresponding local coil may be used to obtain better image quality. The local coil includes, for example, a head coil, a knee coil, a shoulder coil, a spine coil, and a wrist coil.

Either the body coil or the local coil may be selected by means of a switching module to receive the radio frequency excitation pulse. When the local coil is selected, the body coil does not work.

### SUMMARY

Embodiments of the present application provide a magnetic resonance imaging system, and a radio frequency signal processing method and radio frequency coil therefor.

According to an aspect of the embodiments of the present application, a radio frequency local coil for a magnetic resonance system is provided, the radio frequency local coil comprising a flexible main body portion and an extension portion. The flexible main body portion is deformable in a first direction to at least partially surround a region to be scanned of a subject, the flexible main body portion comprising a main body coil circuit. The extension portion is connected to the flexible main body portion, the extension portion comprising a compensation circuit for connecting to the main body coil circuit to form a first radio frequency transmit coil, wherein the compensation circuit has a resonant frequency that is the same as a radio frequency transmit frequency of the magnetic resonance system.

According to an aspect of the embodiments of the present application, a magnetic resonance imaging system is provided, comprising a body coil and a radio frequency local coil according to the above aspect, the radio frequency local coil being configured to electromagnetically couple to the body coil and to receive a radio frequency pulse transmitted by means of the body coil, so as to generate a radio frequency field exciting the subject.

With reference to the following description and drawings, specific implementations of the embodiments of the present application are disclosed in detail, and the way in which the principles of the embodiments of the present application can be employed are illustrated. It should be understood that the embodiments of the present application are not limited in scope thereby. Within the scope of the spirit and clauses of the appended claims, the embodiments of the present application include many changes, modifications, and equivalents.

### BRIEF DESCRIPTION OF THE DRAWINGS

The included drawings are used to provide further understanding of the embodiments of the present application, which constitute a part of the description and are used to illustrate the implementations of the present application and explain the principles of the present application together with textual description. Evidently, the drawings in the following description are merely some embodiments of the present application, and those of ordinary skill in the art may obtain other implementations according to the drawings without involving inventive effort. In the drawings:

FIG. 1 is a schematic diagram of a magnetic resonance imaging system according to an embodiment of the present application;

FIG. 2 is a schematic diagram of a structure of a body coil and a radio frequency local coil according to an embodiment of the present application;

FIG. 3 is a schematic diagram of a structure of a radio frequency local coil according to an embodiment of the present application;

FIG. 4 is a schematic diagram of a structure of a radio frequency local coil in FIG. 3 in an expanded and disassembled state;

FIG. 5 and FIG. 6 are a structural diagram of a body coil and an electrical structural diagram of the body coil, respectively;

FIG. 7 shows a main body coil circuit according to an embodiment of the present application;

FIG. 8 is a structural diagram of a flexible main body portion serving alone as a radio frequency local coil;

FIG. 9 is a schematic diagram of a structure of a radio frequency local coil according to an embodiment of the present application;

FIG. 10 is an example diagram of cooperation between a radio frequency local coil and a region to be scanned according to an embodiment of the present application;

FIG. 11 is an exploded view of a radio frequency local coil according to an embodiment of the present application;

FIG. 12 is a schematic diagram of a radio frequency signal processing method according to an embodiment of the present application;

FIG. 13 is a schematic diagram of a radio frequency signal processing procedure for a conventional local coil;

FIG. 14 is a schematic diagram of a radio frequency signal processing procedure according to an embodiment of the present application; and

FIG. 15 is a schematic diagram of comparison between a reconstructed image obtained by means of a radio frequency local coil according to an embodiment of the present application and a reconstructed image obtained by means of a conventional local coil.

### DETAILED DESCRIPTION

The foregoing and other features of the embodiments of the present application will become apparent from the following description with reference to the drawings. In the description and drawings, specific implementations of the present application are disclosed in detail, and part of the implementations in which the principles of the embodiments of the present application may be employed are indicated. It should be understood that the present application is not limited to the described implementations. On the contrary, the embodiments of the present application include all modifications, variations, and equivalents which fall within the scope of the appended claims.

In the embodiments of the present application, the terms “first”, “second”, etc., are used to distinguish different elements, but do not represent a spatial arrangement or temporal order, etc., of these elements, and these elements should not be limited by these terms. The term “and/or” includes any and all combinations of one or more associated listed terms. The terms “comprise”, “include”, “have”, etc., refer to the presence of described features, elements, components, or assemblies, but do not exclude the presence or addition of one or more other features, elements, components, or assemblies.

In the embodiments of the present application, the singular forms “a”, “the”, etc., include plural forms, and should be broadly construed as “a type of” or “a class of” rather than being limited to the meaning of “one”. Furthermore, the term “the” should be construed as including both the singular and plural forms, unless otherwise specified in the context. In addition, the term “according to” should be construed as “at least partially according to . . . ” and the term “based on” should be construed as “at least partially based on . . . ”, unless otherwise explicitly specified in the context.

The features described and/or illustrated for one implementation may be used in one or more other implementations in the same or similar way, be combined with features in other embodiments, or replace features in other implementations. The terms “include/comprise” when used herein refer to the presence of features, integrated components, steps, or assemblies, but do not preclude the presence or addition of one or more other features, integrated components, steps, or assemblies.

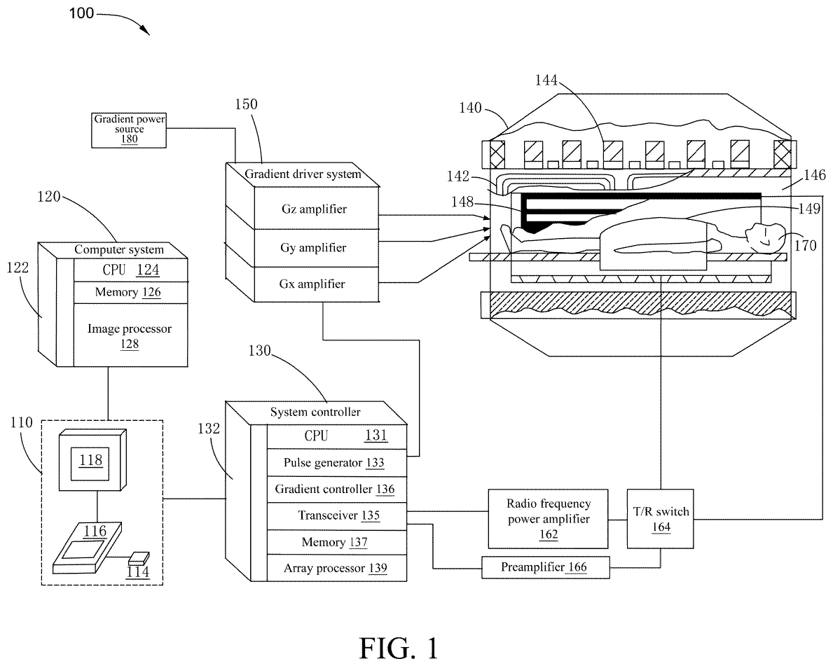

For ease of understanding, FIG. 1 shows a magnetic resonance system 100 according to some embodiments of the present invention.

The operation of the magnetic resonance system 100 is controlled by an operator workstation 110 that includes an input device 114, a control panel 116, and a display 118. The input device 114 may be a joystick, a keyboard, a mouse, a trackball, a touch-activated screen, voice control, or any similar or equivalent input device. The control panel 116 may include a keyboard, a touch-activated screen, voice control, a button, a slider, or any similar or equivalent control device. The operator workstation 110 is coupled to and in communication with a computer system 120 that enables an operator to control the generation and display of images on the display 118.

The computer system 120 includes various components that communicate with one another by means of an electrical and/or data connection module 122. The connection module 122 may employ a direct wired connection, a fiber optic connection, a wireless communication link, etc. The computer system 120 may include a central processing unit (CPU) 124, a memory 126, and an image processor 128. In some embodiments, the image processor 128 may be replaced by image processing functions implemented in the CPU 124. The computer system 120 may be connected to an archive media device, a persistent or backup memory, or a network. The computer system 120 may be coupled to and communicate with a separate system controller 130.

The system controller 130 includes a set of components that communicate with one another by means of an electrical and/or data connection module 132. The connection module 132 may employ a direct wired connection, a fiber optic connection, a wireless communication link, etc. The system controller 130 may include a CPU 131, a pulse generator 133 communicating with the operator workstation 110, a transceiver (or an RF transceiver) 135, a memory 137, and an array processor 139. In some embodiments, the pulse generator 133 may be integrated into the resonance assembly 140 of the magnetic resonance system 100.

a subject (or a patient) 170 may be positioned within the cylindrical imaging volume 146 of the resonance assembly 140.

The system controller 130 may receive a command from the operator workstation 110 to indicate a scan sequence that is to be executed during a magnetic resonance scan performed on the subject 170. The “scan sequence” above refers to a combination of pulses that have specific intensities, shapes, timings, and the like and that are applied when a magnetic resonance scan is performed. The pulses may typically include, for example, a radio frequency pulse and a gradient pulse. A plurality of scan sequences may be pre-stored in the computer system 120, so that a sequence suitable for clinical examination requirements can be indicated by means of the operator workstation. The clinical examination requirements may include, for example, an imaging site, an imaging function, an imaging effect, scanning safety, and the like. The pulse generator 133 of the system controller 130 sends, based on the indicated sequence, an instruction describing the timings, intensities, and shapes of a radio frequency pulse and a gradient pulse in the sequence so as to operate a system component that executes the sequence.

A radio frequency pulse in the scan sequence sent by the pulse generator 133 may be generated by the transceiver 135, and the radio frequency pulse is amplified by a radio frequency power amplifier 162. The amplified radio frequency pulse is provided to the radio frequency transmit coil, such as the body coil 148 by means of a transmit/receive switch (T/R switch) 164, and the radio frequency transmit coil then immediately provides a transverse magnetic field B₁. As a non-limiting example, a transmitting portion of the transceiver 135, the radio frequency power amplifier 162, the T/R switch 164, and the like constitute at least a portion of a radio frequency transmit link. The transverse magnetic field B₁ is substantially perpendicular to B₀ throughout the cylindrical imaging volume 146, and the transverse magnetic field B₁ is used to excite stimulated nuclei within the body of the subject 170, thereby generating a magnetic resonance signal.

The system controller 130 further provides gradient waveforms to the gradient driver system 150, and the gradient driver system includes Gₓ (x direction), G_{y} (y direction), and G_{z} (z direction) amplifiers, etc. Each of the Gₓ, G_{y}, and G_{z} amplifiers excites a corresponding gradient coil in the gradient coil assembly 142, so as to generate a magnetic field gradient for spatially encoding a magnetic resonance signal during a magnetic resonance scan. The gradient coil assembly 142 is disposed within the resonance assembly 140. The x direction may also be referred to as a frequency encoding direction or a kx direction in the k-space. The y direction may be referred to as a phase encoding direction or a ky direction in the k-space. Gₓ can be used for frequency encoding or signal readout, and is generally referred to as a frequency encoding gradient or a readout gradient. G_{y} can be used for phase encoding, and is generally referred to as a phase encoding gradient. G_{z} can be used for slice (layer) position selection to obtain k-space data. It should be noted that a layer selection direction, a phase encoding direction, and a frequency encoding direction may be modified according to actual requirements.

The resonance assembly 140 further includes a superconducting magnet having a superconducting coil 144 that, in operation, provides a static uniform longitudinal magnetic field B₀ throughout the cylindrical imaging volume 146.

The resonance assembly 140 further includes a body coil 148, which may be configured to transmit a radio frequency pulse, and in operation thereof in the transmit mode, provide a transverse magnetic field B₁, the transverse magnetic field B₁ being substantially perpendicular to B₀ throughout the cylindrical imaging volume 146. The body coil 148 may be further configured to receive a magnetic resonance signal from the scanned subject. The body coil 148 may be configured by the transmit/receive switch (T/R switch) 164 to operate in the transmit mode or the receive mode. Specifically, the T/R switch 164 may be controlled by a signal from the system controller 130 to electrically connect, during the transmit mode, the radio frequency power amplifier 162 to the RF body coil 148 and to connect, during the receive mode, the preamplifier 166 to the RF body coil 148.

A radio frequency local coil (or surface coil) 149 may be further provided, and the body coil, the radio frequency local coil, or the surface coil may be employed to receive a magnetic resonance signal generated by the scanned subject. The magnetic resonance signal may be sent back to the preamplifier 166 through the T/R switch 164.

In some embodiments, the magnetic resonance signal sensed and received by any one of the above coils and amplified by the preamplifier 166 is stored as a raw k-space data array in the memory 137 for post-processing. A reconstructed magnetic resonance image may be obtained by transforming/processing the stored raw k-space data.

In some embodiments, the magnetic resonance signal sensed and received by the coil and amplified by the preamplifier 166 is demodulated, filtered, and digitized in a receiving portion of the transceiver 135, and transmitted to the memory 137 in the system controller 130. For each image to be reconstructed, the data is rearranged into separate k-space data arrays, and each of said separate k-space data arrays is input to the array processor 139, the array processor being operated to transform the data into an array of image data by Fourier transform.

The array processor 139 uses transform methods, most commonly Fourier transform, to reconstruct images from the received magnetic resonance signal. These images are transmitted to the computer system 120 and stored in the memory 126. In response to commands received from the operator workstation 110, the image data may be stored in a long-term memory, or may be further processed by the image processor 128 and transmitted to the operator workstation 110 for presentation on the display 118.

In various embodiments, components of the computer system 120 and the system controller 130 may be implemented on the same computer system or on a plurality of computer systems. The system controller 130 and the image processor 128 may separately or collectively include a computer processor and a storage medium. The storage medium records a predetermined data processing program to be executed by the computer processor. For example, the storage medium may store a program used to implement scanning processing (such as a scan flow and an imaging sequence), image reconstruction, image processing, etc. For example, the storage medium may store a program used to implement the magnetic resonance imaging method according to the embodiments of the present invention. The described storage medium may include, for example, a ROM, a floppy disk, a hard disk, an optical disk, a magneto-optical disk, a CD-ROM, or a non-volatile memory card.

It should be understood that the magnetic resonance system 100 shown in FIG. 1 is intended for illustration. A suitable magnetic resonance system may include more, fewer, and/or different components.

As described above, the body coil 148 may be configured to transmit a radio frequency signal and to receive a magnetic resonance signal, although in general a local coil may also be employed to receive a magnetic resonance signal. The local coil includes, for example, a knee coil, a shoulder coil, a spine coil, a wrist coil, and a head and neck coil. The local coil is typically positioned close to the patient and thus provides a higher signal-to-noise ratio (SNR).

At present, a common local coil adopts a phased array coil composed of a plurality of coil components. Each type of local coil needs to be equipped with a respective cable and receive channel for transmitting a magnetic resonance signal. The local coil has a cable interface for connecting to one end of the cable. The other end of the cable is connected to a cable interface disposed on an examination table. A magnetic resonance signal received from the local coil is transmitted to a receive chain module of the local coil through the cable, amplified by a radio frequency preamplifier, then demodulated, filtered, analog-to-digital converted, pre-processed, Fourier transformed and so on, and finally reconstructed into a magnetic resonance image.

The phased array coil typically includes a decoupling circuit. In some embodiments, the decoupling circuit may be used for electromagnetic decoupling between the receive coil and the radio frequency transmit coil during radio frequency transmission to avoid affecting the transmit field.

The inventors have also found that a decoupling circuit included in the phased array coil requires direct current (DC) power to operate, so the coil array also needs to rely on cables for DC power supply, but this increases the difficulty in wiring. In addition, to improve the image quality, the number of receive channels is increasing. For example, the number of receive channels is 16 or 32 or 64 or the like, which undoubtedly further increases the complexity of the cable interface and the cable and increases costs.

Although some local coils are also capable of transmitting a radio frequency excitation signal and receiving a magnetic resonance signal (self-transmission and self-reception), in addition to requiring the receive cable, the receive channel, and the decoupling circuit described above, the local coils further need to be electrically connected to the radio frequency transmit link to receive a radio frequency excitation pulse from the radio frequency transmit link. This also increases the difficulty in wiring. In addition, the electrical structure of such a local coil is typically disposed on a hard material.

In view of at least one of the above technical problems, the embodiments of the present application provide a magnetic resonance imaging system, and a radio frequency signal processing method and radio frequency coil therefor. The embodiments of the present application are specifically described below.

Embodiments of the present application provide a radio frequency local coil for a magnetic resonance imaging system, the radio frequency local coil being configured to cooperate with a region to be scanned of a subject (for example, a subject 170) and to be coupled in the magnetic resonance system in a cable-free connection manner. For example, the radio frequency local coil may be configured to wrap/surround/cover/be in close proximity to the region to be scanned of the subject, and the region to be scanned includes a local body part of the subject, such as a shoulder, a head, a knee, a limb, an ankle joint, and a wrist joint. The radio frequency local coil is configured to couple to a body coil (for example, a body coil 148 in FIG. 1) of the magnetic resonance system to receive a radio frequency pulse transmitted from the body coil, so as to generate a radio frequency field exciting the subject 170. The radio frequency local coil further sends, to the body coil, a magnetic resonance signal received from the subject 170, thereby implementing a magnetic resonance scan performed on the region to be scanned of the subject 170.

In some embodiments, a transmit chain module of the magnetic resonance system generates a digital pulse waveform according to a specified scan sequence, and converts the digital pulse waveform into an analog signal. The analog signal is amplified by a radio frequency amplifier and transmitted to the body coil by means of a transmission cable, to drive the body coil to transmit a radio frequency excitation pulse. The body coil may be a quadrature coil, but the embodiments of the present application are not limited thereto. Those skilled in the art understand that the quadrature coil is also a birdcage-like coil. For implementations of the quadrature coil, reference may be made to related techniques, and details are not described herein.

In some embodiments, during scanning, the radio frequency local coil is disposed in a scanning space defined by the body coil. The radio frequency local coil at least partially surrounds the region to be scanned of the subject, that is, the radio frequency local coil is located between the body coil and the subject. In other words, the radio frequency local coil is closer to the subject than the body coil.

In some embodiments, the radio frequency local coil is a flexible coil including at least two portions connected to each other to adapt to the shape and the body configuration of the region to be scanned of the subject, the at least two portions being connected such that respective electrical structures thereof are connected to form a quadrature coil, thereby forming an electromagnetic structure that is the same or approximately the same as that of the body coil.

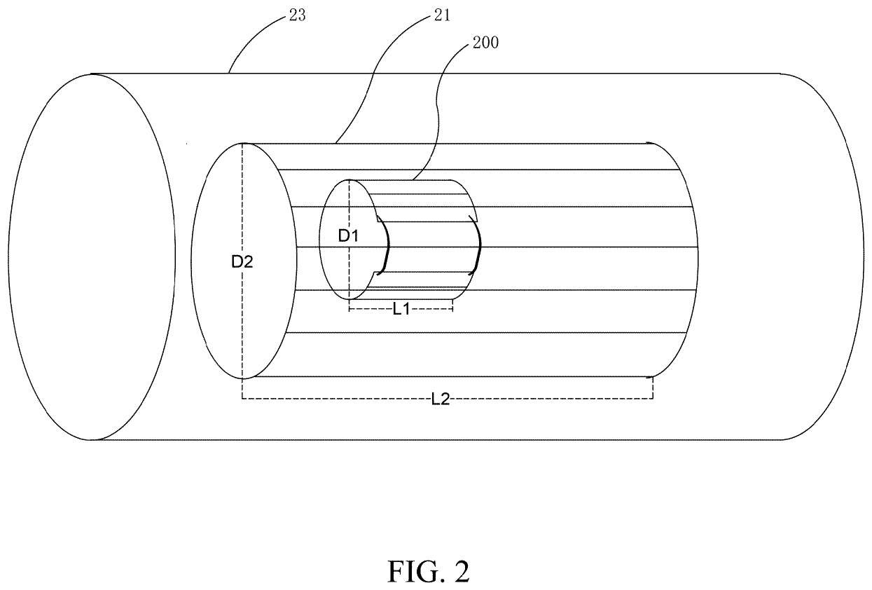

FIG. 2 is a schematic diagram of a structure of a body coil and a radio frequency local coil 200 according to an embodiment of the present application. As shown in FIG. 2, a layer of radio frequency shielding 23 is introduced between a body coil 21 and a gradient coil (not shown). When the body coil 21 is of a birdcage-like structure (a quadrature coil), the radio frequency local coil 200 is also of an approximately birdcage-like structure, and an electrical structure thereof constitutes a quadrature coil. During scanning, the radio frequency local coil 200 is located within the body coil 21, and is disposed at a region to be imaged of the subject. The volume of the radio frequency local coil 200 is smaller than the volume of the body coil 21. For example, the maximum length L1 of the radio frequency local coil is smaller than the maximum length L2 of the body coil 21, and the maximum diameter D1 of the radio frequency local coil is smaller than the maximum diameter D2 of the body coil 21. However, the values of the length and the diameter of the radio frequency local coil 200 are related to the region to be imaged. The embodiments of the present application are not limited thereto. In some embodiments of the present application, the radio frequency local coil 200 has the same electrical or electromagnetic structure as the body coil 21. An example in which each of the body coil 21 and the radio frequency local coil 200 is of a birdcage-like structure is used above, but the embodiments of the present application are not limited thereto. When the body coil 21 has another electrical structure, the radio frequency local coil 200 may also correspondingly include a similar electrical structure.

The principles of electromagnetism are employed such that during scanning, the radio frequency local coil 200 is close to the body coil so as to generate electromagnetic coupling, which is strong. Therefore, when the body coil 21 transmits a radio frequency pulse, a current may be induced in the radio frequency local coil 200, that is, the radio frequency pulse may be transferred from the body coil 21 to the radio frequency local coil 200 by using the induced magnetic field. The radio frequency pulse transferred to the radio frequency local coil 200 generates a uniform magnetic field B1, and excites the region to be scanned of the subject to generate resonance, so as to generate a transverse magnetization vector. After the transmission of the radio frequency pulse is completed (after the magnetic field B1 is removed), the transverse magnetization vector attenuates in a spiral shape until the transverse magnetization vector returns to zero. A free induction attenuation signal is generated in the process of attenuation. The free induction attenuation signal can be sensed and received by the radio frequency local coil 200 as a magnetic resonance signal. Similarly, when the radio frequency local coil receives the magnetic resonance signal, a current may be induced in the body coil 21, that is, the magnetic resonance signal may be transferred from the radio frequency local coil 200 to the body coil 21 by using the induced magnetic field, and be transmitted to a receive chain module of the system by means of a transmission cable connected to the body coil 21, and reconstructed into a magnetic resonance image after processing.

In some embodiments, electromagnetic coupling (mutual inductance) is generated between the body coil 21 and the radio frequency local coil 200 in a wireless manner to transmit and receive radio frequency signals. Unlike the conventional local coil that needs to be equipped with a respective cable, receive channel, and/or transmit chain connection cable for the transmission of a magnetic resonance signal, the radio frequency local coil 200 does not need to be electrically connected to other structures in the magnetic resonance imaging system. In other words, the radio frequency local coil 200 is independent and may implement self-transmission and self-reception of a radio frequency signal without being provided with a cable interface or connected to an examination table by means of a cable. Therefore, a magnetic resonance scan on a local region of the subject may be implemented using only the receive link and the transmit link of the system connected to the body coil 21 without: providing DC power for switching the transmit/receive modes, disposing a decoupling circuit in the conventional coil array structure, or disposing an additional receive chain module and/or a transmit chain module (for example, disposing a receive chain module and/or a transmit chain module corresponding to the conventional coil array). To be specific, radio frequency signals are transmitted and received through electromagnetic coupling between the body coil 21 and the radio frequency local coil 200 in the absence of a cable and a cable interface. Thus, the wiring problem of the magnetic resonance system can be simplified, simplifying the circuit structure, improving the reliability, reducing the failure rate, reducing the costs, and facilitating picking and placement.

In addition, when the body coil 21 transmits a radio frequency pulse, due to the smaller volume of the radio frequency local coil 200, the coupled energy is less. Compared with the body coil 21 directly transmitting a radio frequency pulse to generate the field B1, the radio frequency coil can excite the subject to generate the same field B1 by using less energy, thereby achieving a lower radio frequency energy absorption rate (SAR) and saving more energy.

In addition, when the subject to be examined is located in a scanning chamber, the body coil 21 is farther away from the region to be imaged, and cannot generate a stronger magnetic field near the center of the region to be imaged. By transmitting and receiving radio frequency signals with a small volume radio frequency local coil 200 that is closer to the region to be imaged and similar in size to the region to be imaged, the subject can be excited to generate the same field B1 by using less energy such that the signal-to-noise ratio can be further improved.

In addition, the radio frequency coil employs the same electromagnetic structure as the body coil, for example, a birdcage-like coil structure such that a more uniform magnetic field can be generated, further improving the signal-to-noise ratio.

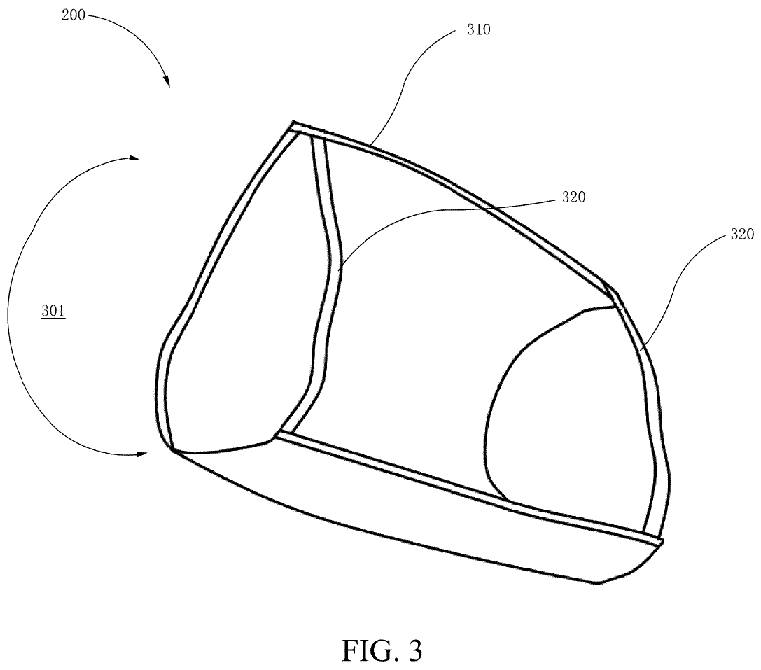

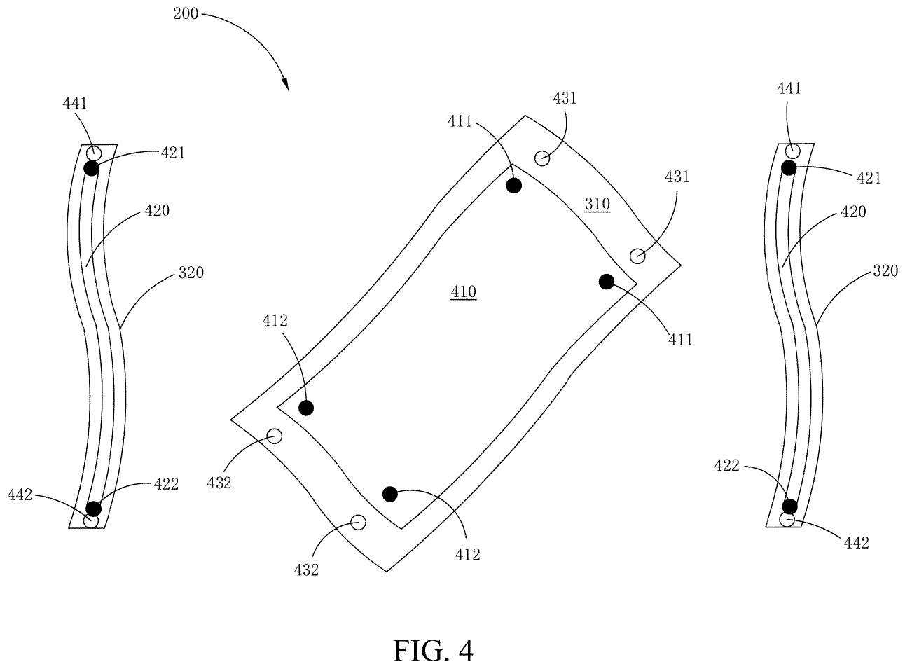

The structure of the radio frequency local coil will be described in detail below with reference to the accompanying drawings. FIG. 3 is a schematic diagram of a structure of a radio frequency local coil 200 according to an embodiment of the present application. FIG. 4 is a schematic diagram of a structure of a radio frequency local coil 200 in FIG. 3 in an expanded and disassembled state. Referring to FIG. 3 and FIG. 4, the radio frequency local coil 200 includes a flexible main body portion 310 and an extension portion 320. The flexible main body portion 310 is deformable in a first direction to at least partially surround a region to be scanned of a subject, the flexible main body portion 310 including a main body coil circuit 410.

The extension portion 320 is connected to the flexible main body portion 310. The extension portion 320 includes a compensation circuit 420, and the compensation circuit 420 is configured to connect to the main body coil circuit 410 to form a first radio frequency transmit coil. The compensation circuit 420 has a resonant frequency that is the same as a radio frequency transmit frequency of the magnetic resonance system.

Those skilled in the art understand that the above “radio frequency transmit frequency of the magnetic resonance system” is a proton precession frequency determined according to a parameter of the magnetic resonance system. For example, the radio frequency transmit frequency (center frequency) is about 63.86 MHz for a 1.5T magnetic resonance system and about 127.8 MHz for a 3T magnetic resonance system. Those skilled in the art further understand that the resonant frequency of the compensation circuit 420 may have a specific error from a theoretical proton precession frequency or an actual radio frequency transmit frequency (such an error may be allowed or inevitable), and the present embodiment defines that the resonant frequency of the compensation circuit is the same as the radio frequency transmit frequency of the magnetic resonance system, which includes a case wherein such an error exists.

The required resonant frequency may be achieved by setting an electrical parameter of the compensation circuit.

An electrical parameter of the main body coil circuit 410 may be set such that the body coil circuit has the same resonant frequency. In this case, when the body coil circuit is connected to the compensation circuit 420, the compensation circuit 420 is actually equivalent to being short-circuited with the main body coil circuit 410 at the resonant frequency of the magnetic resonance system. Therefore, the compensation circuit 420 does not change the operating frequency of the main body coil circuit 410 when connected to the main body coil circuit.

The above first direction may be a direction in which the flexible main body portion 310 is curled (or bent) and expanded approximately along an arcuate surface (for example, a plane on which an arc line 301 is located). For example, the flexible main body portion 310 may be expanded in a sheet-like shape, and when the radio frequency local coil 300 needs to be employed to scan a region to be scanned, one side of the sheet-like flexible main body portion 310 may be curled toward the other side thereof to at least partially surround (or sleeve or wrap) the region to be scanned, or both sides of the sheet-like flexible main body portion may be simultaneously curled toward each other to form a substantially cylindrical space therein to accommodate the region to be scanned.

An example of the above first radio frequency transmit coil is a quadrature coil (for example, an electrical structure of a birdcage-like coil), and when the body coil has another electrical structure, the main body coil circuit and the compensation circuit may be designed to be connected to form the another electrical structure.

To adapt to a body configuration of the region to be scanned, such as a shoulder, a space formed by deformation of the flexible main body portion 310 may not be completely closed (or the flexible main body portion 310 may be deformed into an incompletely closed ring), for example, the flexible main body portion may surround only the outside of the shoulder, which may affect a working parameter and performance of the main body coil circuit 410 therein. In an embodiment of the present application, by connecting the extension portion 320 to the flexible main body portion 310, the extension portion 320 can not only serve to fix the flexible main body portion 310 (for example, the extension portion may surround a neck, an axilla, or another body part to prevent the flexible main body portion 310 from disengaging from the shoulder), but the compensation circuit 420 in the extension portion 320 can be connected to the main body coil circuit to form a first transmit coil (or a first quadrature coil), thereby compensating for a parameter and performance loss caused by incomplete closure of the flexible main body portion 310.

It is described above that the flexible main body portion 310 and the extension portion 320 are used in cooperation for magnetic resonance imaging of the region to be scanned. However, at least part of the extension portion 320 may be removed from the flexible main body portion 310 such that the flexible main body portion 310 is used as a separate radio frequency local coil. For example, for a region such as a knee or a wrist, the flexible main body portion 310 may be deformed into a closed ring to sleeve such a region for magnetic resonance imaging. For the closed ring, the main body coil circuit therein can form a second transmit coil (for example, a second quadrature coil) with parameter and performance needs meeting imaging requirements.

To be specific, at least part of the extension portion 320 is detachably connected to the flexible main body portion 310, and when the at least part of the extension portion 320 is not connected to the flexible main body portion 310, the main body coil circuit 410 and the compensation circuit 420 are electrically disconnected.

Specifically, as shown in FIG. 4, the main body coil circuit 410 includes a first connection point 411 and a second connection point 412, and the compensation circuit 420 includes a third connection point 421 and a fourth connection point 422. The flexible main body portion 310 includes a first connection portion 431 and a second connection portion 432, and the extension portion 320 includes a third connection portion 441 and a fourth connection portion 442. The first connection portion 431 of the flexible main body portion 310 is electrically connected to the first connection point 411 of the main body coil circuit 410, and the second connection portion 432 of the flexible main body portion 310 is electrically connected to the second connection point 412 of the main body coil circuit 410. In this embodiment of the present application, the flexible main body portion 310 may include, for example, an electrical inner layer and an outer wrapping layer, the main body coil circuit 410 may be disposed on the electrical inner layer, the outer wrapping layer is configured to provide insulation and protection for the circuit on the electrical inner layer, and the first connection portion 431 and the second connection portion 432 may be disposed on the outer wrapping layer and electrically connected to the first connection point 411 and the second connection point 412, respectively, on the electrical inner layer through the outer wrapping layer. The third connection portion 441 and the fourth connection portion 442 of the extension portion 320 may also be electrically connected to the third connection point 421 and the fourth connection point 422, respectively, of the compensation circuit 420 in a similar manner.

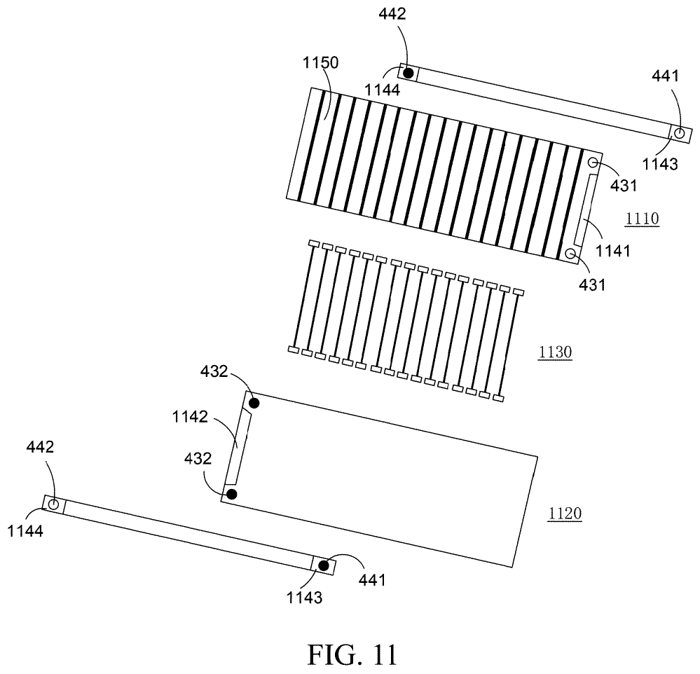

The third connection portion 441 and the fourth connection portion 442 of the extension portion 320 are configured to mechanically connect to the first connection portion 431 and the second connection portion 432 of the flexible main body portion 310, respectively. In addition, when the third connection portion 441 and the fourth connection portion 442 are mechanically connected to the first connection portion 431 and the second connection portion 432, respectively, the third connection point 421 and the fourth connection point 422 are electrically connected to the first connection point 411 and the second connection point 412, respectively. When the third connection portion 441 is not mechanically connected to the first connection portion 431 or the fourth connection portion 442 is not mechanically connected to the second connection portion 432, the compensation circuit 420 is electrically disconnected from the main body coil circuit 410. For example, each of the first connection portion 431, the second connection portion 432, the third connection portion 441, and the fourth connection portion 442 may have a function of performing electrical conduction and mechanical connection with the outside, for example, may include a hook, a buckle, and a hoop made of a conductive material, or may implement electrical conduction only by using a conductive material, implement mechanical connection by using a non-conductive material (for example, an adhesive material), and implement electrical contact or electrical connection between conductive materials while implementing mechanical connection. Mechanical mechanisms of the flexible main body portion 310 and the extension portion 320 are described by way of example below with reference to FIG. 11.

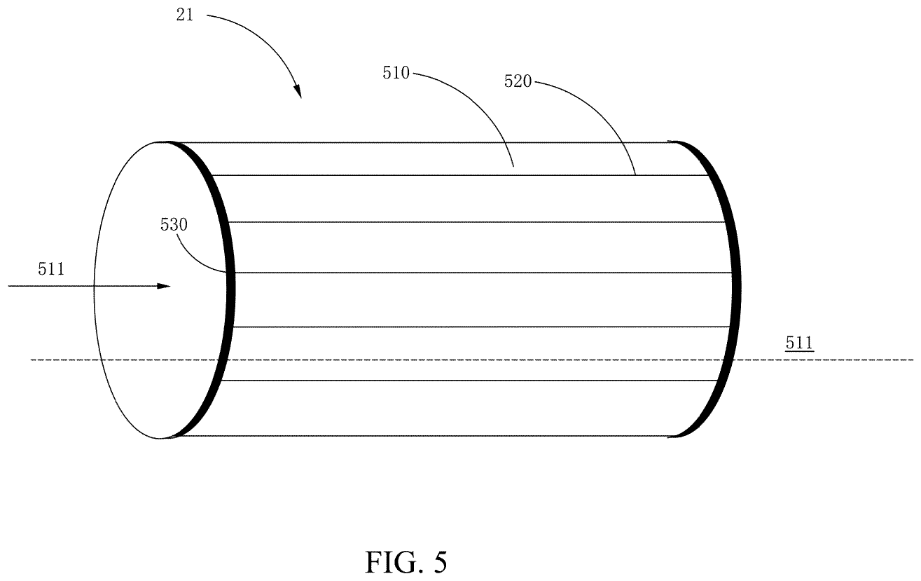

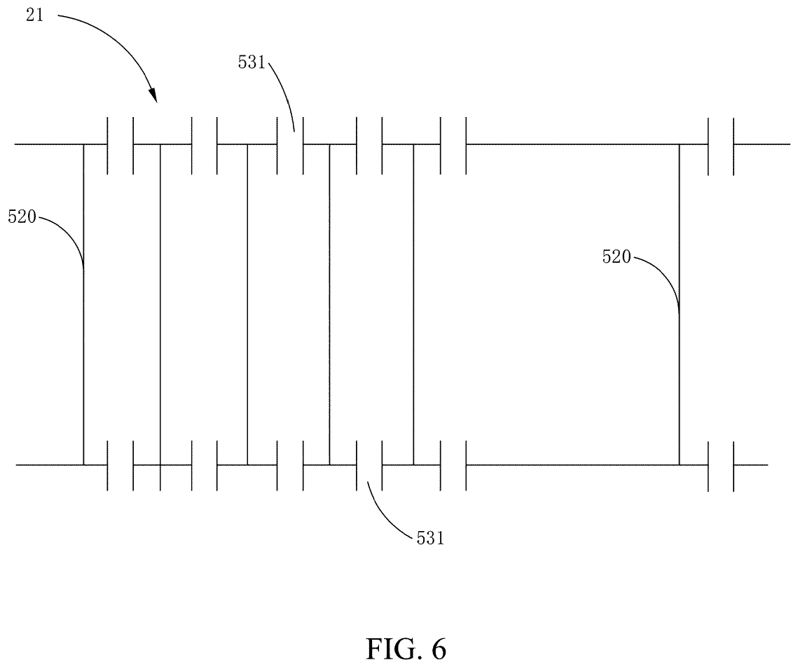

FIG. 5 and FIG. 6 show a structural diagram of a body coil 21 and an electrical structural diagram of the body coil 21, respectively. The body coil 21 includes a ring-shaped carrier 510, a plurality of conductive strips 520 are disposed in parallel at intervals on a surface of the ring-shaped carrier 510, a length direction of each conductive strip 520 is along an axial direction of the ring-shaped carrier 510, and end rings 530 are disposed at both ends of the ring-shaped carrier 510, respectively, wherein resonance capacitors 531 between adjacent conductive strips 520 are provided.

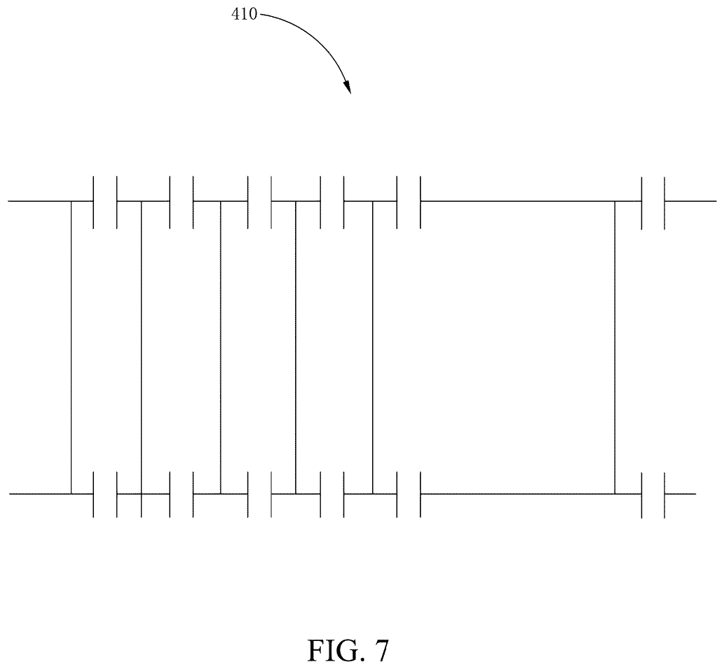

FIG. 7 shows a main body coil circuit 410. In an embodiment of the present application, the main body coil circuit 410 has the same circuit structure as a body coil of the magnetic resonance system when the body coil is expanded. For example, when the ring-shaped carrier 510 is expanded into a plane along an axial tangent 511, a circuit structure therein is the same as that of the main body coil circuit 410 shown in FIG. 7.

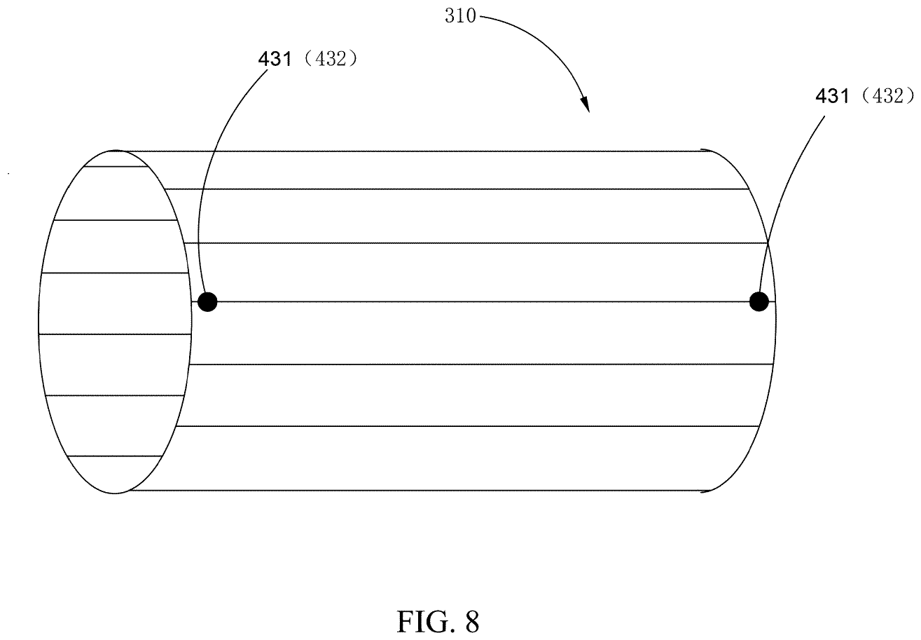

FIG. 8 is a structural diagram of a flexible main body portion 310 serving alone as a radio frequency local coil. In an embodiment of the present application, the first connection portion 431 and the second connection portion 432 of the flexible main body portion 310 can be mechanically connected in a manner similar to the manner in which the flexible main body portion 310 and the extension portion 320 are connected. For example, when the second connection portion 432 and the first connection portion 431 are mechanically connected, the first connection point 411 and the second connection point 412 of the main coil circuit 410 are electrically connected to form a second quadrature coil. Specifically, when the first connection portion 431 and the second connection portion 432 are connected, the flexible main body portion 310 forms a closed ring, forming a coil structure similar in structure to the body coil 21 shown in FIG. 5, but smaller in volume than the body coil 21. Further, the second quadrature coil formed alone by the flexible main body portion 310 also has the same electrical structure as the body coil 21.

In this embodiment of the present application, when the flexible main body portion 310 serves alone as a radio frequency local coil, the resonant frequency of the second quadrature coil formed by the flexible main body portion is the same as the resonant frequency of the body coil 21, i.e., the radio frequency transmit frequency of the magnetic resonance system, which may be implemented by setting a parameter of the main body coil circuit 410 as understood by those skilled in the art.

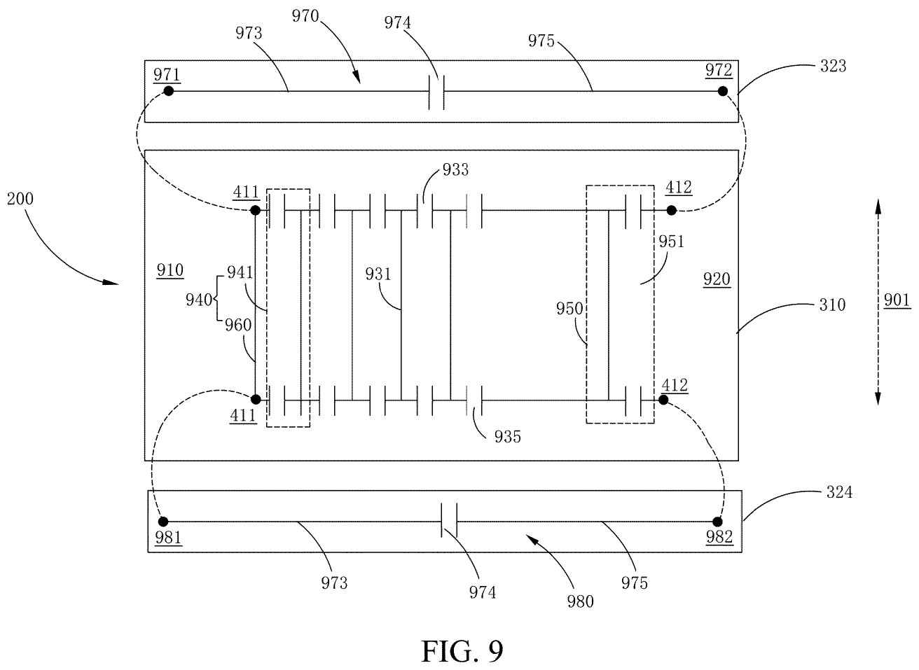

FIG. 9 shows a radio frequency local coil 200 with a flexible main body portion 310 being expanded in a sheet-like shape. The flexible main body portion 310 has a first side 910 and a second side 920 that are opposite to each other. The main body coil circuit 410 includes N coil units sequentially distributed from the first side 910 to the second side 920, the N coil units being connected in parallel, the N coil units including a 1st coil unit 940 (for example, at the first side 910) and an Nth coil unit 950 (for example, at the second side 920) located at edges, wherein N is an integer greater than 1. In an embodiment of the present application, a value of N may be taken based on the number of receive channels, for example, N may be 8, 16, or 32. The above first connection point 411 includes an electrical node on the 1st coil unit 940, and the second connection point includes an electrical node on the Nth coil unit 950.

The 1st coil unit 940 includes a common portion 960 for sharing with the Nth coil unit 950. The 1st coil unit 940 and the Nth coil unit 950 have non-common portions 941, 951, respectively. The common portion 960 is located on the first side 910 of the flexible main body portion 310, the first connection point 411 includes an electrical node of the common portion 960, and the second connection point 412 includes an electrical node of the non-common portion 951 of the Nth coil unit 950.

Further referring to FIG. 9, as described above, the main body coil circuit 410 may have the same electrical structure of the body coil 21 when the body coil is expanded. Specifically, the main body coil circuit 410 includes N conductive strips 931 sequentially disposed from the first side 910 to the second side 920 of the flexible main body portion 310, each of the conductive strips 931 having a first end and a second end extending in a second direction 901, the second direction 901 being perpendicular to a plane on which the first direction is located. The main body coil circuit 410 further includes N first capacitors 933 and N second capacitors 935 sequentially distributed from the first side 910 to the second side 920 of the flexible main body portion 310, wherein first ends of the 1st to Nth first capacitors 933 are respectively connected to the first ends of the 1st to Nth conductive strips 931, second ends of the 1st to (N−1)th first capacitors 933 are respectively connected to the second ends of the 2nd to Nth conductive strips 931, first ends of the 1st to Nth second capacitors 935 are respectively connected to the second ends of the 1st to Nth conductive strips 931, and second ends of the 1st to (N−1)th second capacitors 935 are respectively connected to the second ends of the 2nd to Nth conductive strips 931.

The first connection point 411 of the main body coil circuit 410 includes the first end and the second end of the 1st conductive strip 931 (i.e., the common portion 960 of the 1st coil unit 940), and the second connection point includes the second end of the Nth first capacitor 933 and the second end of the Nth second capacitor 935 (i.e., the non-common portion 951 of the Nth coil unit 950).

The compensation circuit 420 includes a first compensation circuit 970 having a first electrical node 971 and a second electrical node 972, and a second compensation circuit 980 having a first electrical node 981 and a second electrical node 982. The third connection point 421 of the compensation circuit 420 includes the first electrical node 971 of the first compensation circuit 970 and the first electrical node 981 of the second compensation circuit 980, and the fourth connection point 422 of the compensation circuit 420 includes the second electrical node 972 of the first compensation circuit 970 and the second electrical node 982 of the second compensation circuit 980.

The first end and the second end of the 1st conductive strip 931 are configured to connect to the first electrical node 971 of the first compensation circuit 970 and the first electrical node 981 of the second compensation circuit 980, respectively. The second end of the Nth first capacitor 933 is configured to connect to the second electrical node 972 of the first compensation circuit 970, and the second end of the Nth second capacitor 935 is configured to connect to the second electrical node 982 of the second compensation circuit 980.

In this embodiment of the present application, at the radio frequency transmit frequency of the magnetic resonance system, the compensation circuit 420 may be equivalent to a short-circuit connection line between the common portion 960 and the non-common portion 951 of the Nth coil unit 950 because the resonant frequency of the compensation circuit 420 is the same as the resonant frequency of the main body coil circuit 410. When the flexible main body portion 310 (for example, due to the body configuration of the scanned region) does not form a closed ring, the common portion 960 of the 1st coil unit 940 has an increased spatial distance from the non-common portion 951 of a last coil unit (the Nth coil unit 950), thus generating a parameter loss, and the compensation circuit 420 is equivalent to filling the increased spatial distance and compensating for the parameter loss.

Further referring to FIG. 9, the first compensation circuit 970 and the second compensation circuit 980 each include a series resonance circuit including a first inductance component 973, a capacitance component 974, and a second inductance component 975 connected in series, wherein an end (the first electrical node 971, 981) of the first inductance component 973 not connected to the capacitance component 974 serves as the third connection point 421, and an end (the second electrical node 972, 982) of the second inductance component 975 not connected to the capacitance component 974 serves as the fourth connection point 422.

Referring to FIG. 9, in this embodiment of the present application, the extension portion 320 includes a first extension portion 323 and a second extension portion 324, the first extension portion 323 and the second extension portion 324 being configured to carry the first compensation circuit 970 and the second compensation circuit 980, respectively.

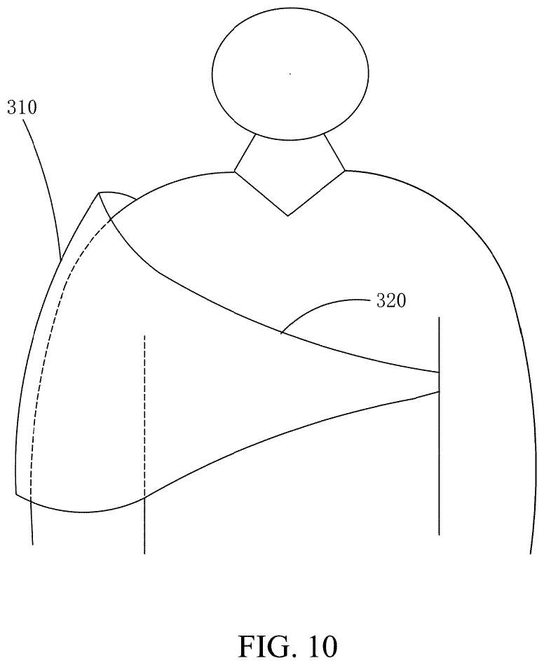

Referring to FIG. 2 and FIG. 10, in an embodiment of the present application, the extension portion 320 includes a ribbon structure and is configured to surround a local region of the subject other than the region to be scanned such that the flexible main body portion is fixed with respect to the region to be scanned. FIG. 10 shows an example of cooperation between a radio frequency local coil and a region to be scanned according to an embodiment of the present application. When the radio frequency local coil in this embodiment of the present application is used for shoulder scanning, the flexible main body portion 310 may wrap the shoulder, and the extension portion 320 may be fixed around an opposite side of the shoulder (for example, an axilla on the other side of the body), wherein the first extension portion 323 and the second extension portion 324 are connected into a whole (for example, may carry both the first compensation circuit 970 and the second compensation circuit 980). The first extension portion 323 and the second extension portion 324 may alternatively be disposed separately. For example, the first extension portion 323 may be, for example, fixed around the neck portion, and the second extension portion 324 may be fixed around the axilla.

Although only an example of applying the radio frequency local coil to the shoulder is shown above, the radio frequency local coil in this embodiment of the present application may further include at least one of a head coil, a knee coil, an ankle joint coil, an abdomen coil, an elbow coil, a chest coil, a spine coil, a neck coil, and a shoulder coil.

Although the above embodiment mainly shows the electrical structure in which the quadrature coil is formed, there may be another electrical structure capable of being electromagnetically coupled to the body coil for radio frequency signal transmission and/or reception, and the numbers and positions of the above connection portions and connection points, as well as the number of compensation circuits and positions of the compensation circuits for connecting to the main body coil circuit, and the like may be changed based on the change of the coil circuit.

FIG. 11 is an exploded view of a radio frequency local coil according to an embodiment of the present application. The flexible main body portion 310 of the radio frequency local coil may include a three-layer structure, namely, a first mechanical layer 1110, a second mechanical layer 1120, and an electrical layer 1130 carrying the main body coil circuit 410, the electrical layer 1130 being arranged between the first mechanical layer 1110 and the second mechanical layer 1120.

In some embodiments, the electrical layer 1130 is a coil layer. In a closed state, the electrical layer constitutes a birdcage-like structure, forming a second quadrature coil. In an opened state, the flexible main body portion may be expanded in a sheet-like shape.

In some embodiments, by lamination molding, the first mechanical layer 1110 and the second mechanical layer 1120 are fixedly connected to the electrical layer 1130 through heating or pressurization, and the electrical layer 1130 is wrapped between the first mechanical layer 1110 and the second mechanical layer 1120. The first mechanical layer 1110 and the second mechanical layer 1120 may be made of a flexible insulating material (which may alternatively be but is not limited to being cleansing, waterproof, flame retardant, or lightweight), such as one or a plurality of an elastomeric material, a polyester material, cotton, wool, or foam, but the embodiments of the present application are not limited thereto. The first mechanical layer 1110 may also be referred to as an inner layer, and the second mechanical layer 1120 may also be referred to as an outer layer. In the opened state, a first connection portion 431 is disposed on one side (for example, the first side 910) of the sheet-like structure of the first mechanical layer 1110, and a second connection portion 432 is disposed on the other side (for example, the second side 920) of the sheet-like structure of the second mechanical layer 1120. The first connection portion 431 and the second connection portion 432 are connected and fixed, or cooperate with each other such that the flexible main body portion is changed from the sheet-like structure to a closed birdcage-like structure. In this way, the flexible main body portion can sleeve a region such as a knee or a limb.

For example, in a rectangular area of the sheet-like structure, the first connection portion 431 and the second connection portion 432 are respectively disposed at two edges (corresponding to the first side 910 and the second side 920 of the flexible main body portion) parallel to a length direction (for example, the second direction 901) of a rung, wherein two first connection portions 431 may be respectively disposed at two end points of one of the edges, and the two first connection portions 431 are electrically connected to two electrical nodes 1131, 1132 on the electrical layer 1130 (i.e., the two ends of the 1st conductive strip 931 located on the first side 910), respectively, through the first mechanical layer 1110. Two second connection portions 432 may be respectively disposed at two end points of the other edge, and the two second connection portions 432 are electrically connected to two electrical nodes (i.e., the second end of the Nth first capacitor 933 and the second end of the Nth second capacitor 935 located on the second side 920) on the electrical layer 1130, respectively, through the second mechanical layer 1120. To be specific, the first connection portion 431 may be disposed on the first mechanical layer 1110, i.e., the first connection portion 431 is disposed on an inner surface of the flexible main body portion 310, and the second connection portion 432 is disposed on the second mechanical layer 1120, i.e., the second connection portion 432 is disposed on an outer surface of the flexible main body portion 310. The sheet-like structure is bent into a cylindrical shape such that the first connection portion and the second connection portion on both sides of the sheet-like structure are connected and fixed to form a second quadrature coil.

Similar to the flexible main body portion 310, the first extension portion 323 and the second extension portion 324 may also form a three-layer structure in a similar manner, wherein a third connection portion 441 may be disposed on an outer surface of one end of each of the first extension portion 323 and the second extension portion 324, and a fourth connection portion 442 may be disposed on an inner surface of the other end of each of the first extension portion 323 and the second extension portion 324. When the first connection portion 431 is not connected to the second connection portion 432, the third connection portion 441 of the first extension portion 323 is connected and fixed to one of the first connection portions 431, the third connection portion 441 of the second extension portion 324 is connected and fixed to the other first connection portion 431, the fourth connection portion 442 of the first extension portion 323 is connected and fixed to one of the second connection portions 432, and the fourth connection portion 442 of the second extension portion 324 is connected and fixed to the other second connection portion 432, thereby forming a first quadrature coil.

In the example of FIG. 11, the first connection portion 431 and the fourth connection portion 442 may be a female connector (or a male connector) of a metal buckle, and the second connection portion 432 and the third connection portion 441 may be a male connector (or a female connector) of a metal buckle. For ease of distinguishing, in FIG. 11, the male connector is indicated by a solid circle, and the female connector is indicated by a hollow circle.

In other embodiments, the flexible main body portion 310 may include only the first connection portion 431 without providing the second connection portion 432, and the extension portion 320 may include only the third connection portion 441, and one end of the extension portion may be integrally formed with the flexible main body portion 310 without providing the fourth connection portion 442. Assembly and disassembly between the extension portion and the flexible main body portion are implemented through connection or detachment between the first connection portion 431 and the third connection portion 441, thereby helping prevent parts from being lost during use.

In other embodiments, both ends of the extension portion may be integrally formed with both sides of the flexible main body portion, respectively, without being disposed as a detachable structure, thereby helping enhance the reliability of electrical connection.

In some embodiments, to further ensure a fixed connection, a first mechanical connection portion 1141 may be disposed on an outer surface of the flexible main body portion 310, a second mechanical connection portion 1142 may be disposed on an inner surface of the flexible main body portion 310, a third mechanical connection portion 1143 may be disposed on an inner surface of one end of the extension portion 320, and a fourth mechanical connection portion 1144 may be disposed on an outer surface of the other end of the extension portion 320. The second mechanical connection portion 1142 may be cooperatively connected to the first mechanical connection portion 1141, and the fourth mechanical connection portion 1144 may be cooperatively connected to the second mechanical connection portion 1142. The first to fourth mechanical connection portions do not need to be electrically connected to the electrical layer, and may be made of an insulating material, for example, may be an elongated adhesive fastener, and may be, for example, disposed separately from each connection portion connecting to the electrical layer.

In some embodiments, the first mechanical layer 1110 of the flexible main body portion 310 may have a specific thickness such that there are wrinkles in the bent state. Therefore, at least one groove 1150 may be further disposed on the surface of the first mechanical layer 1110 of the flexible main body portion 310. The extension direction of the at least one groove 1150 is parallel to the length direction of the conductive strip, the length of the at least one groove is approximately the same as the width of the first mechanical layer 1110, and the depth of the at least one groove is less than or equal to the thickness of the first mechanical layer 1110. Through the at least one groove, the flexible main body portion is more easily bent, and the inner layer is wrinkle-free in the bent state, improving the comfort of the subject to be examined.

Based on the above description, embodiments of the present application may further provide a magnetic resonance system including a body coil and a radio frequency local coil according to the embodiments of the present application, the radio frequency local coil being configured to electromagnetically couple to the body coil and to receive a radio frequency pulse transmitted by means of the body coil, so as to generate a radio frequency field exciting the subject.

Further, the radio frequency local coil is further configured to send, to the body coil, a magnetic resonance signal received from the subject.

The embodiments of the present application may further provide a radio frequency signal processing method for a magnetic resonance imaging system. The same content as that of the foregoing embodiments will not be described again.

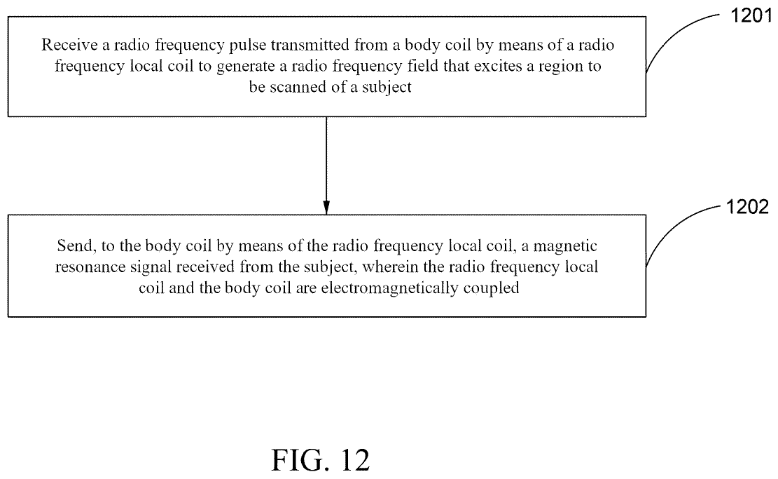

FIG. 12 is a schematic diagram of a radio frequency signal processing method according to an embodiment of the present application. As shown in FIG. 12, the method includes steps 1201 and 1202. Step 1201 includes receiving a radio frequency pulse transmitted from a body coil by means of a radio frequency local coil to generate a radio frequency field that excites a region to be scanned of a subject. Further, step 1202 includes sending, to the body coil by means of the radio frequency local coil, a magnetic resonance signal received from the subject, wherein the radio frequency local coil and the body coil are electromagnetically coupled.

In some embodiments, during scanning, the flexible main body portion of the radio frequency local coil is opened, and bent and deformed to at least partially surround a region to be detected of the subject, and when the flexible main body portion is not completely closed, the foregoing third and fourth connection portions are connected and fixed to the foregoing first and second connection portions, respectively, to ensure that the extension portion is connected to the flexible main body portion to form the first quadrature coil, and the extension portion cooperates with the body part to fix the flexible main body portion such that the radio frequency local coil enters the center of the scanning chamber along with the subject to be detected. When the flexible main body portion is bent and deformed to be completely closed, the first and second connection portions are connected and fixed such that the extension portion alone forms the second quadrature coil and enters the center of the scanning chamber along with the subject to be detected.

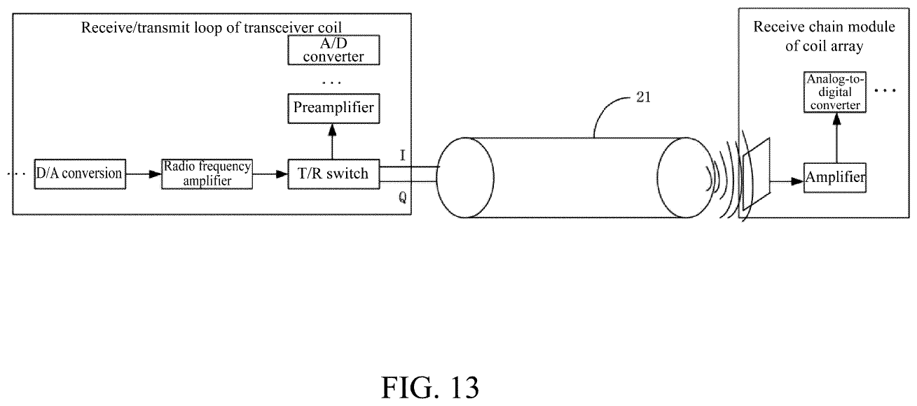

FIG. 13 is a schematic diagram of a radio frequency signal processing procedure for a conventional local coil. As shown in FIG. 13, after a scanning protocol is set, a transmit link of a magnetic resonance system generates a digital pulse waveform according to a selected scan sequence, and the digital pulse waveform is converted into an analog signal by a digital-to-analog (D/A) converter. The analog signal is amplified by a radio frequency power amplifier and transmitted to a body coil by means of a transmission cable, and drives the body coil 21 (for example, set to a transmit mode by a T/R switch, and orthogonally fed power for the body coil 21 through I and Q paths) to transmit a radio frequency pulse. A uniform magnetic field B1 that excites a subject to be examined is generated to excite the subject to be examined to generate resonance, so as to generate a transverse magnetization vector. After the transmission of the radio frequency pulse is completed (after the magnetic field B1 is removed), the transverse magnetization vector attenuates in a spiral shape until the transverse magnetization vector returns to zero. A free induction attenuation signal is generated in the process of attenuation. The free induction attenuation signal can be sensed and received by a local receive coil as a magnetic resonance signal, and is transmitted to a receive chain module corresponding to the local receive coil by means of a cable. The receive chain module includes modules such as an amplifier and an analog-to-digital converter. Finally, a magnetic resonance image is reconstructed. Reference may be made to related techniques for details. In addition, there is a decoupling circuit of a coil array structure for electromagnetic decoupling between the local receive coil and the body coil during radio frequency transmission to avoid affecting the transmit field.

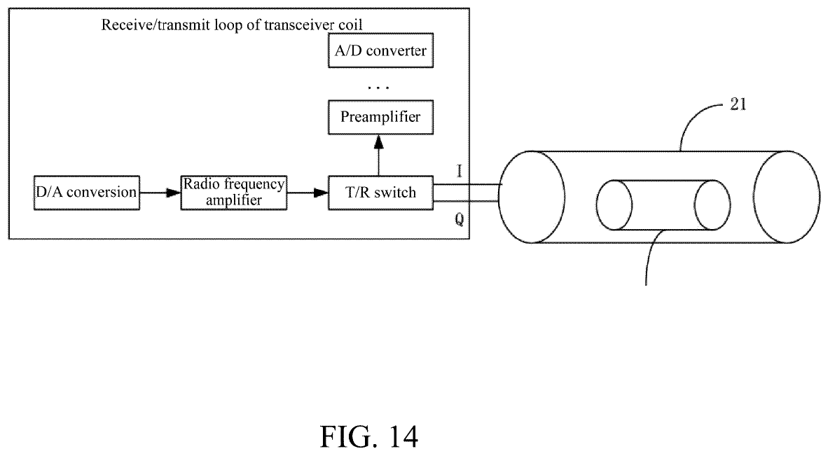

FIG. 14 is a schematic diagram of a radio frequency signal processing procedure according to an embodiment of the present application. In some embodiments, as shown in FIG. 14, after a scanning protocol is set, a transmit link of a magnetic resonance system generates a digital pulse waveform according to a selected scan sequence, and the digital pulse waveform is converted into an analog signal by a digital-to-analog (D/A) converter. The analog signal is amplified by a radio frequency power amplifier and transmitted to a body coil by means of a transmission cable, and drives the body coil (for example, set to a transmit mode by a T/R switch, and orthogonally fed power for the body coil through I and Q paths) to transmit a radio frequency pulse. A radio frequency local coil according to this embodiment of the present application is disposed in a scanning space defined by the body coil, and the radio frequency local coil and the body coil generate electromagnetic coupling. Therefore, a current may be induced in the radio frequency local coil, that is, the radio frequency pulse may be transferred from the body coil to the radio frequency local coil by using the induced magnetic field. The radio frequency pulse transferred to the radio frequency local coil generates a uniform magnetic field B1 that excites a subject to be detected, and excites the subject to be detected to generate resonance, so as to generate a transverse magnetization vector. After the transmission of the radio frequency pulse is completed (after the magnetic field B1 is removed), the transverse magnetization vector attenuates in a spiral shape until the transverse magnetization vector returns to zero. A free induction attenuation signal is generated in the process of attenuation. The free induction attenuation signal can be sensed and received by the radio frequency local coil as a magnetic resonance signal. Similarly, when the radio frequency local coil receives the magnetic resonance signal, a current may be induced in the body coil, that is, the magnetic resonance signal may be transferred from the radio frequency local coil to the body coil by using the induced magnetic field, and be transmitted to a receive link of the body coil by means of a transmission cable connected to the body coil, be amplified by a preamplifier, and then be demodulated, filtered, pre-processed by an analog-to-digital converter, subject to Fourier transform, and so on, and finally be reconstructed into a magnetic resonance image.

Since the radio frequency coil is independent, the radio frequency coil may implement self-transmission and self-reception of a radio frequency signal without being provided with a cable interface or connected to an examination table by means of a cable. Therefore, the magnetic resonance image may be reconstructed using only the receive link of the system connected to the body coil without: providing DC power for switching the transmit/receive modes, disposing a decoupling circuit in the conventional coil array structure, or disposing an additional receive chain module (for example, disposing a receive chain module corresponding to the conventional coil array, such as an amplifier, an analog-to-digital converter, and a like module) in FIG. 14 compared with FIG. 13. To be specific, radio frequency signals are transmitted and received through electromagnetic coupling between the body coil and the radio frequency local coil in the absence of a cable and a cable interface. Thus, the wiring problem of the magnetic resonance system can be simplified, simplifying the circuit structure, improving the reliability, reducing the failure rate, and reducing the costs.

It is worth noting that only the components or modules related to the present application have been described above, but the present application is not limited thereto. The receive/transmit link in FIG. 14 may further include other components or modules. For details about these components or modules, reference may be made to related techniques.

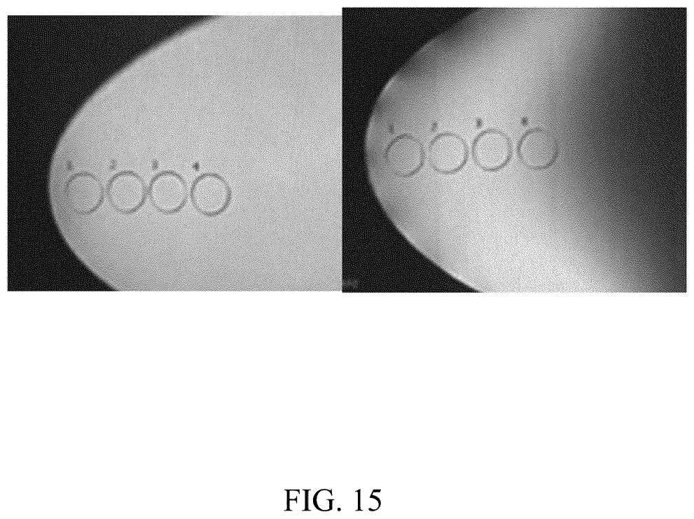

FIG. 15 is a schematic diagram of comparison between a reconstructed image obtained by means of a radio frequency local coil according to an embodiment of the present application and a reconstructed image obtained by means of a conventional local coil. As shown in FIG. 15, the left image is a reconstructed image obtained by means of the radio frequency local coil according to the present application, and the right image is a reconstructed image obtained using a conventional local receive coil. The left reconstructed image has better uniformity and is at a position closer to the joint, and the signal-to-noise ratio of the radio frequency local coil according to the present application can reach the signal-to-noise ratio of the image obtained through the conventional radio frequency local coil, which is favorable for clinical observation for examination more interested in a joint region (typically closer to the center of the image).

In addition, the radio frequency transmit power (TG) can be greatly reduced by using the radio frequency local coil according to this embodiment of the present application. In addition, upon comparison, the image quality obtained when the radio frequency coil is shifted from the center of the scanned region is approximately the same as that obtained when the radio frequency coil is located at the center of the scanned region, and neither the signal-to-noise ratio nor the transmit power varies greatly along with shifting from the position of the center. That is, the radio frequency coil of the present application has lower sensitivity to a change in position, further improving reliability.

The above embodiments merely provide illustrative descriptions of the embodiments of the present application. However, the present application is not limited thereto, and appropriate variations may be made on the basis of the above embodiments. For example, each of the above embodiments may be used independently, or one or more among the above embodiments may be combined.

The above apparatus and method of the present application can be implemented by hardware, or can be implemented by hardware in combination with software. The present application relates to such a computer-readable program that when executed by a logic component, the program causes the logic component to implement the foregoing apparatus or a constituent component, or causes the logic component to implement various methods or steps as described above. The present application further relates to a storage medium for storing the above program, such as a hard disk, a disk, an optical disk, a DVD, a flash memory, etc.

The method/apparatus described in view of the embodiments of the present application may be directly embodied as hardware, a software module executed by a processor, or a combination of the two. For example, one or more of the functional block diagrams and/or one or more combinations of the functional block diagrams shown in the drawings may correspond to either respective software modules or respective hardware modules of a computer program flow. The foregoing software modules may respectively correspond to the steps shown in the figures. The foregoing hardware modules can be implemented, for example, by firming the software modules using a field-programmable gate array (FPGA).

The software modules may be located in a RAM, a flash memory, a ROM, an EPROM, an EEPROM, a register, a hard disk, a portable storage disk, a CD-ROM, or any other form of storage medium known in the art. The storage medium may be coupled to a processor, so that the processor can read information from the storage medium and can write information into the storage medium. Alternatively, the storage medium may be a constituent component of the processor. The processor and the storage medium may be located in an ASIC. The software module may be stored in a memory of a mobile terminal, and may also be stored in a memory card that can be inserted into a mobile terminal. For example, if a device (such as a mobile terminal) uses a large-capacity MEGA-SIM card or a large-capacity flash memory apparatus, the software modules can be stored in the MEGA-SIM card or the large-capacity flash memory apparatus.

One or more of the functional blocks and/or one or more combinations of the functional blocks shown in the accompanying drawings may be implemented as a general-purpose processor, a digital signal processor (DSP), an application-specific integrated circuit (ASIC), a field-programmable gate array (FPGA) or other programmable logic devices, discrete gate or transistor logic devices, a discrete hardware assembly, or any appropriate combination thereof for implementing the functions described in the present application. The one or more functional blocks and/or the one or more combinations of the functional blocks shown in the accompanying drawings may also be implemented as a combination of computing devices, such as a combination of a DSP and a microprocessor, multiple microprocessors, one or more microprocessors in communication combination with a DSP, or any other such configuration.

The present application is described above with reference to specific embodiments. However, it should be clear to those skilled in the art that the foregoing description is merely illustrative and is not intended to limit the scope of protection of the present application. Various variations and modifications may be made by those skilled in the art according to the principle of the present application, and said variations and modifications also fall within the scope of the present application.

1. A radio frequency local coil for a magnetic resonance system, comprising:
a flexible main body portion, deformable in a first direction to at least partially surround a region to be scanned of a subject, the flexible main body portion comprising a main body coil circuit; and
an extension portion, connected to the flexible main body portion, the extension portion comprising a compensation circuit for connecting to the main body coil circuit to form a first radio frequency transmit coil, wherein the compensation circuit has a resonant frequency that is the same as a radio frequency transmit frequency of the magnetic resonance system.

2. The radio frequency local coil according to claim 1, wherein, the main body coil circuit has the same circuit structure as a body coil of the magnetic resonance system when the body coil is expanded.

3. The radio frequency local coil according to claim 1, wherein, at least part of the extension portion is detachably connected to the flexible main body portion, and when the at least part of the extension portion is not connected to the flexible main body portion, the main body coil circuit and the compensation circuit are electrically disconnected.

4. The radio frequency local coil according to claim 3, wherein,
the main body coil circuit comprises a first connection point and a second connection point, and the compensation circuit comprises a third connection point and a fourth connection point;
the flexible main body portion comprises a first connection portion and a second connection portion, and the first connection portion and the second connection portion are electrically connected to the first connection point and the second connection point of the main body coil circuit, respectively;
the extension portion comprises a third connection portion and a fourth connection portion, the third connection portion and the fourth connection portion are electrically connected to the third connection point and the fourth connection point of the compensation circuit, respectively, and the third connection portion and the fourth connection portion are mechanically connected to the first connection portion and the second connection portion, respectively; and
when the third connection portion and the fourth connection portion are mechanically connected to the first connection portion and the second connection portion, respectively, the third connection point and the fourth connection point are electrically connected to the first connection point and the second connection point, respectively; and when the third connection portion is not mechanically connected to the first connection portion, or the fourth connection portion is not mechanically connected to the second connection portion, the compensation circuit is electrically disconnected from the main body coil circuit.

5. The radio frequency local coil according to claim 4, wherein,
the first connection portion and the second connection portion of the flexible main body portion are mechanically connectable; and
when the second connection portion is mechanically connected to the first connection portion, the flexible main body portion forms a closed ring, and the first connection point and the second connection point of the main body coil circuit are electrically connected to form a second radio frequency transmit coil.

6. The radio frequency local coil according to claim 1, wherein, the first radio frequency transmit coil is a quadrature coil.

7. The radio frequency local coil according to claim 4, wherein, the flexible main body portion has a first side and a second side that are opposite to each other; the main body coil circuit comprises N coil units sequentially distributed from the first side to the second side, the N coil units are connected in parallel, and the N coil units comprise a 1st coil unit and an Nth coil unit located at edges, wherein N is an integer greater than 1; and the first connection point comprises an electrical node on the 1st coil unit, and the second connection point comprises an electrical node on the Nth coil unit.

8. The radio frequency local coil according to claim 7, wherein, the 1st coil unit comprises a common portion for sharing with the Nth coil unit, the 1st coil unit and the Nth coil unit each have a non-common portion, the common portion is located on the first side of the flexible main body portion, the first connection point comprises an electrical node of the common portion, and the second connection point comprises an electrical node of the non-common portion of the Nth coil unit.

9. The radio frequency local coil according to claim 8, wherein, the compensation circuit is equivalent to a short-circuit connection line of the common portion and the non-common portion of the Nth coil unit at the radio frequency transmit frequency of the magnetic resonance system.

10. The radio frequency local coil according to claim 7, wherein, the compensation circuit comprises a first compensation circuit having a first electrical node and a second electrical node, and a second compensation circuit having a first electrical node and a second electrical node, the third connection point comprises the first electrical node of the first compensation circuit and the first electrical node of the second compensation circuit, and the fourth connection point comprises the second electrical node of the first compensation circuit and the second electrical node of the second compensation circuit; and the main body coil circuit comprises:
N conductive strips sequentially disposed from the first side to the second side, each conductive strip having a first end and a second end extending in a second direction perpendicular to a plane on which the first direction is located;
N first capacitors sequentially distributed in the first direction, wherein first ends of the 1st to Nth first capacitors are connected to the first ends of the 1st to Nth conductive strips, respectively, and second ends of the 1st to (N−1)th first capacitors are connected to the first ends of the 2nd to Nth conductive strips, respectively; and
N second capacitors sequentially distributed in the first direction, wherein first ends of the 1st to Nth second capacitors are connected to the second ends of the 1st to Nth conductive strips, respectively, and the second ends of the 1st to (N−1)th second capacitors are connected to the second ends of the 2nd to Nth conductive strips, respectively,
wherein, the first connection point comprises the first end and the second end of the 1st conductive strip, the second connection point comprises the second end of the Nth first capacitor and the second end of the Nth second capacitor, the first end and the second end of the 1st conductive strip are used to connect to the first electrical node of the first compensation circuit and the first electrical node of the second compensation circuit, respectively, the second end of the Nth first capacitor is used to connect to the second electrical node of the first compensation circuit, and the second end of the Nth second capacitor is used to connect to the second electrical node of the second compensation circuit.

11. The radio frequency local coil according to claim 10, wherein, the first compensation circuit and the second compensation circuit each comprise a series resonance circuit comprising a first inductance component, a capacitance component, and a second inductance component connected in series, wherein ends of the first inductance component and the second inductance component not connected to the capacitance component serve as the third connection point and the fourth connection point, respectively.

12. The radio frequency local coil according to claim 10, wherein, the extension portion comprises a first extension portion and a second extension portion for carrying the first compensation circuit and the second compensation circuit, respectively.

13. The radio frequency local coil according to claim 1, wherein, the extension portion comprises a ribbon structure and is configured to surround a local region of the subject other than the region to be scanned such that the flexible main body portion is fixed with respect to the region to be scanned.

14. The radio frequency local coil according to claim 1, wherein, the radio frequency local coil comprises at least one of a head coil, a knee coil, an ankle joint coil, an abdomen coil, an elbow coil, a chest coil, a spine coil, a neck coil, and a shoulder coil.

15. A magnetic resonance system, comprising:
a body coil; and
the radio frequency local coil according to claim 1, the radio frequency local coil being configured to electromagnetically couple to the body coil and to receive a radio frequency pulse transmitted by means of the body coil, so as to generate a radio frequency field exciting the subject.

16. The magnetic resonance system according to claim 15, wherein, the radio frequency local coil is further configured to send, to the body coil, a magnetic resonance signal received from the subject.
